(19) United States
(12) Patent Application Publication
(10) Pub. No.: US 2012/0328797 A1
(43) Pub. Date: Dec. 27, 2012

(54) METHOD AND DEVICE FOR RAPIDLY HEATING AND COOLING A SUBSTRATE AND IMMEDIATELY SUBSEQUENTLY COATING THE SAME UNDER VACUUM

(76) Inventors: Wolfram Maass, Linsengericht-Grossenhausen (DE); Berthold Ocker, Hanau (DE); Jürgen Langer, Offenbach (DE); Helmut John, Obertshausen (DE)

(21) Appl. No.: 13/261,400

(22) PCT Filed: Feb. 22, 2011
(86) PCT No.: PCT/EP11/52600

§ 371 Date: Aug. 10, 2012

(30) Foreign Application Priority Data
Feb. 24, 2010 (EP) 10154561.4

(51) Int. Cl. H01L 21/687; B05D 3/00; F25B 29/00; B05D 3/06

(52) U.S. Cl. 427/557; 427/294; 165/61; 165/80.2

(57) ABSTRACT

The invention relates to a method for heating/cooling and coating a substrate in a vacuum chamber, comprising the following steps: (1) arranging the lower face of the substrate on a substrate holder, (2) lifting the substrate by a predefined distance relative to the substrate holder, and (3) heating the lifted substrate via its upper face by means of a heating device such as a radiant heating device, (4) coating the hot substrate, for example by moving it in or through a coating zone, (5) cooling the substrate by lowering it onto the chuck and (6) optionally further coating the cold substrate. The method according to the invention further enables process sequences to be executed, wherein various defined temperatures can be set on the substrate during each step, and optionally one or more coating processes can be executed immediately subsequently at said substrate temperature. Also included is the case, for example, that a substrate can be held at a higher temperature for a certain time immediately after a coating process (tempering).

### FIELD OF INVENTION

The present invention relates to a method and a device for heating and/or cooling a substrate in a vacuum chamber. The heated substrate can then, e.g., immediately afterwards be provided with a specific coating and subsequently cooled to a lower temperature.

### BACKGROUND TO INVENTION

Coating substrates with thin layers under vacuum by means of sputtering (PVD), chemical vapor deposition (CVD), evaporation and further methods are generally methods that are often used in industry for making specific functional layers. Typical examples are the semiconductor industry and in the meantime also the solar industry for producing solar cells. Without intending to restrict the usability of the method presented herein, this method should be explained exemplarily on the basis of the production of specific magnetic multi-layers.

The production of well defined thin layers and multi-layers on a substrate in a vacuum chamber is important, e.g., for realizing magnetic tunnel contacts. Such magnetic tunnel contacts are essential elements of MRAMs (magneto-resistive random access memory), but they are also used, e.g., as magnetic field sensors for reading stored information in thin layer heads of hard disks. Here, the so-called TMR (tunnel magneto resistance) effect or also the so-called GMR (giant magneto resistance) effect becomes effective. An example of a typical layer package is shown in FIG. 1.

The layers 1, 2 (having specific magnetic orientations, “pinned layers”) and 3 (“free layer”) are made of a ferromagnetic material. The shown arrows indicate the direction of the magnetization which lies in the layer plane. The thicknesses of the individual layers vary from less than 1.0 nm to some 10.0 nm.

Latest developments show that it is necessary for the production of highly dense MRAMs to orientate the magnetization direction at least in some of the ferromagnetic layers present in the layer stack perpendicularly with respect to the layer plane. Such a perpendicular orientation of the magnetization can be achieved, i.a., in that specific ferromagnetic alloys (e.g. CoPt, FePt, FePd) are applied to a hot substrate by means of cathode sputtering. The required temperatures of the substrate lie in the range of 250° C. to 500° C. However, other layers in the layer stack must, as before, be deposited onto the substrate at room temperature in order to achieve the required properties.

In the field of writing and reading heads for magnetic hard disks, the use of specific ferromagnetic materials having a high spin polarization can be advantageous in layer systems being constructed in a manner similar to that shown in FIG. 1. The mentioned materials are above all the so-called Heusler alloys. For achieving the desired layer properties it is also in this case necessary that the material is applied to a hot substrate. However, here too, other layers in the layer stack must be applied to the substrate at room temperature.

Also in other coating processes—not only in connection with magneto-resistive sensors—the application of thin layers onto substrates at a well-defined—mostly high—temperature alternating with other “cold” process steps can be desirable.

For coating processes of this kind, which normally take place in a vacuum chamber, thus a plurality of conditions and aspects must be taken into consideration.
(a) In general, the above-mentioned thin layer systems should be produced in the shortest possible time. In this regard, it is almost always important to keep the time between the depositions of the individual layers very short in order not to deteriorate the quality of the boundaries between the layers. On the other hand, long production processes would lead to a bad productivity. Typical coating times are some seconds up to some ten seconds. The breaks between the individual depositions should also be in this range.
(b) For being coated in a vacuum chamber, substrates are typically held on a substrate holder. In case of silicon wafers which are used, e.g., for producing semiconductors, the substrate holder is mostly a cooled holding device.
(c) During the coating processes, the substrate should mostly have a specific temperature (depending on the layer material). However, at present it is not possible to quickly heat or cool the substrate to another temperature and then, e.g., coat it immediately. If, e.g., heating and cooling should be realized via the holding device, the holding device would have to be cooled from the mentioned high temperatures within a short time again to room temperature, which seems to be particularly difficult because cooling by means of convection is not possible in a vacuum and such holding devices necessarily have a relatively large (also thermal) mass.
(d) In the semiconductor industry, often a single layer is deposited onto a hot substrate. In this case the technical solution is to coat the substrate in a specific vacuum chamber equipped with a heatable wafer holder (chuck). This chuck is permanently held at the high temperature, and the wafer is placed onto the hot chuck for being coated. After coating, the wafer is moved, if necessary, into a further process chamber, e.g., by using a vacuum robot, in order to carry out further (e.g. “cold”) process steps.
   This way of applying coatings to hot substrates, however, cannot be successfully used for the mentioned magnetic and other multi-layers, wherein individual layers require different substrate temperatures. As discussed under (a), transporting the substrate in most cases several times from one vacuum coating chamber into another one and back again would not be acceptable, either in terms of process technology or for economical reasons (throughput).
(e) In the semiconductor industry it is also a common method to bring substrates in specific vacuum chambers quickly to a high temperature by using infrared radiators (RTP—rapid thermal processing). It is not possible to coat the substrates in vacuum chambers of this kind because the position of the coating tool is taken by the radiant heater.

Therefore, it is an object of the present invention to provide a method and a device for quickly heating and cooling a substrate in a controlled manner and for coating it immediately subsequently in only one vacuum chamber. In accordance with the invention it is possible to carry out this procedure of tempering the substrate (heating or cooling) and subsequently coating it several times sequentially in order to be able to produce multi-layers with a respective defined substrate temperature for the individual coating processes.

This object is achieved by the subject-matter of the claims.

### SUMMARY OF THE INVENTION

The invention starts out from the basic idea to lift the (hot) substrate from the (cooled) substrate holder for heating and optionally coating this substrate. Therefore, the substrate holder can remain in this cooled state so that the heated substrate is cooled again when it is later lowered onto the cooled holder. In this way it is possible to realize short heating and cooling times of a substrate and immediately afterwards coat it in the vacuum chamber.

The invention relates to a method for heating/cooling and coating a substrate in a vacuum chamber, comprising the following steps: (1) arranging the lower face of the substrate onto a substrate holder, (2) lifting the substrate by a predefined distance relative to the substrate holder and (3) heating the lifted substrate via its upper face by means of a heating device such as a radiant heating device, (4) coating the heated substrate, for example by moving it in or through a coating zone, (5) cooling the substrate by lowering it onto the chuck and (6) optionally applying a further coating to the cold substrate.

According to the invention it is moreover possible to carry out process sequences in which defined different temperatures are set on the substrate in the individual steps and—optionally—immediately subsequently one or more coatings are applied at this substrate temperature. This also includes the case in which a substrate can be held for a certain time at a relatively high temperature directly after coating (tempering).

A substrate in the meaning of the invention can be, e.g., a silicon wafer or another carrier which has either already been coated or not. The vacuum chamber, which comprises the heating and coating devices, can be part of an overall system to which further process chambers are connected. According to the invention, a transport device, such as a robot (arm), can be provided in the vacuum chamber in order to move the substrate to and fro, possibly together with the substrate holder. Gas present in the vacuum chamber can be removed from the chamber by using, e.g., vacuum pumps so that, e.g., a vacuum of less than 10⁻⁷, in particular less than 10⁻⁸, preferably 10⁻⁹ mbar or also less is achieved in the vacuum chamber.

When the substrate lies on the substrate holder, its lower face is in face-to-face contact with the substrate holder. The upper face of the substrate, which is to be coated after heating, should typically not come in contact with the substrate holder.

By placing the lower face of the substrate onto the substrate holder, the substrate is made available for the further treatment of its upper face. The substrate holder can, e.g., fix the substrate by means of electrostatic forces (electrostatic chuck, ESC). Depending on the size of the substrate, substrate or wafer holders of this kind can have a considerable mass of, e.g., some kilograms.

Substrate holders of this kind can be realized in different manners. It is essential that a plane surface is provided. For example, the substrate holder can have a recess into which the substrate can be placed, or it can be plane so that the lower face of the substrate can be placed against or onto this plane side/surface of the holder. In both cases the holder can be provided with fingers or grippers which can be sunk in the holder and swiveled away from it and/or can be moved or swiveled out of the holder so that, by using them, the substrate can be lifted relative to the rest of the holder. Preferably, the dimensions of the contact surfaces between the fingers or grippers and the substrate are as small as possible, e.g., less than 10%, in particular less than 5%, typically less than 1% of the surface of the lower face of the substrate (the upper face and the lower face of the substrate have the same size in all practical cases). Alternatively or also additionally, the substrate holder can also be configured such that the fingers or grippers hold the substrate while the rest of the holder moves downwardly.

According to an embodiment, the substrate holder comprises at least two, in particular thee or four fingers and/or at least one gripper. Here, the fingers can be, e.g., narrow shanks having, e.g., a diameter of less than 2 mm. A gripper can, e.g., be configured such that it grips the substrate at its lower face and one side, wherein the contact surfaces with the substrate do not exceed the above-mentioned ranges. A gripper can also be a (picture) frame-shaped device or a part of a frame (e.g. consisting only of the corners of the frame), onto/into which the substrate is placed and thus has a very small contact surface with the substrate holder, as mentioned above.

According to an embodiment, the fingers or the gripper(s) can be made of a material (e.g. ceramics) which is only slightly or practically not heat conducting. Thus, as little heat energy as possible is transmitted from the just being heated or already heated substrate to the (possibly even cooled) substrate holder.

According to an embodiment, the substrate holder is cooled.

For example, the substrate holder can be cooled by using water and, for this purpose, comprise corresponding cooling channels. For an improved conduction of heat energy from the substrate lying on the substrate holder to the substrate holder, contact gas channels can be provided in its otherwise plane contact surface with the substrate, e.g., in the form of grooves, for conveying helium or argon as a contact agent between the substrate and the substrate holder.

Thus, for example, a heated substrate can be cooled after having been coated and/or before being coated (again), or it can also quickly and effectively be brought to a desired temperature in case of other process parameters.

According to an embodiment, the substrate is lifted by 0.1 to 20 mm, in particular by 1 to 10 mm, preferably by 2 to 5 mm.

Thus, heat conduction to the colder substrate holder is prevented practically completely so that the substrate can be heated effectively and quickly.

The substrate is heated by means of a heating device, in particular a radiant heating device, which is located in the vacuum chamber and used for heating the substrate to a specific temperature. This temperature can be set, e.g., before the heating process from outside.

Typically, the substrate which has been brought to a desired temperature is coated in a lifted position. In contrast thereto, a cooled substrate can typically be coated in the lowered state and in close contact with the plane cooled surface of the substrate holder.

For example, the heated substrate can be brought in the lifted state within a few seconds, in particular within less than 2 seconds, into the coating position in the vacuum chamber in which it can be coated. For this purpose, a coating device is, e.g., integrated such in the vacuum chamber that the substrate holder with the lifted and heated substrate can easily and quickly be brought in the direction of this coating device. The procedure in connection with a cooled substrate in the lowered state is the same. The coating device can also be provided in a neighboring chamber so that the substrate holder with the substrate can be moved into this neighboring chamber by means of a robot (arm).

According to an embodiment, the substrate is moved in a direction parallel to the lower face of the substrate.

For example, the coating device can be located in the vacuum chamber next to the heating position so that this coating device can be reached by laterally moving the substrate with the substrate holder parallel to the substrate surface.

Thus, the substrate can be transported quickly and easily, and the coating of the substrate that has been brought to a specific temperature can start without any further delay.

According to an embodiment, heating of the lifted substrate is controlled by a sensor.

This sensor can, e.g., be a pyrometer which is located in the vacuum chamber and measures the actual temperature of the substrate. The sensor or the pyrometer can alternatively be outside the vacuum chamber and determine the temperature of the substrate, e.g., through a window in the chamber. Typical pyrometers provide for a very small measurement area of about 1 mm² at a distance of 40 cm between the pyrometer and the substrate. Compared to a temperature measurement using a thermo-element in the chamber, the pyrometric measurement through a window in the chamber is advantageous because the pyrometric sensor does not have to be in contact with the substrate and, if applicable, is not attacked by reactive gases in the process chamber. According to a particular embodiment, the pyrometer can be connected with a controller which in turn can be programmed by a PC so that the results of the pyrometer can be analyzed such that the heater can be actuated or also readjusted accordingly in order to set the correct temperature of the substrate and, if necessary, also keep it constant.

In this way, even relatively complicated temperature sequences of the substrate can be controlled precisely and easily, in particular in case of a subsequent coating.

After coating, it might be advantageous to cool the substrate to a lower temperature and in particular subsequently coat it again. This can be done, e.g., by lowering the substrate onto the (colder) substrate holder.

According to an embodiment, the substrate is cooled in a controlled manner.

A controlled cooling of the substrate can, e.g., be realized in that the substrate holder is cooled in a controlled manner. For example, it can be possible to couple the sensor or the pyrometer with the controller for the cooler of the substrate holder so that a substrate that has been lowered to the substrate holder can be cooled to a specific temperature.

According to a further embodiment, a heat accumulator which has in particular been brought before to a desired temperature can be introduced between the lifted substrate and the substrate holder in order to compensate for a possible temperature drop of the substrate. The heat accumulator can have, e.g., a large thermal mass and can preferably be black on its side facing the substrate but can be prepared such on all other surfaces or at least on the surface facing the substrate holder that the radiation of heat into the chamber or in the direction of the substrate holder is minimized. This heat accumulator can, e.g., also be moved to and fro together with the substrate and the substrate holder for the purpose of coating in order to avoid a considerable cooling of the substrate during the coating process.

According to an embodiment, prior to a subsequent coating, the substrate is kept at a specific temperature for a relatively long time, in particular some minutes, preferably at least 10 minutes.

According to an embodiment of the method of the invention, the substrate is heated and/or cooled sequentially to various, specific temperatures, in particular in connection with a subsequent coating. To this end, a controller can be provided for controlling the sequence of the method steps, e.g., in several individual steps in case the substrate is coated several times.

The invention also relates to a system for heating a substrate in a vacuum chamber. The system comprises a substrate holder, a lifting device for lifting the substrate which is arranged with its lower face on the substrate holder, and a heating means for heating the lifted substrate via its upper face.

Features that have been described in connection with the method of the invention can be as advantageous as features of the system of the invention and vice versa. The explanations of the described features of the method should likewise be applicable to the features of the system of the invention.

According to an embodiment, the lifting device is provided at the substrate holder. In other words, the lifting device can, e.g., be integrated in the substrate holder. For example, the lifting device can comprise the fingers and/or the gripper(s) as described above.

According to an embodiment, the lifting device is configured such that a significant heat flow between the substrate holder and the substrate in the lifted state is prevented.

According to an embodiment, the substrate holder's surface facing the substrate comprises at least one contact gas channel for conveying contact gas in order to increase the heat transfer between substrate and substrate holder.

According to an embodiment, the system comprises a controller for cooling the substrate holder in a controlled manner.

According to an embodiment, the system comprises a temperature sensor for heating the substrate in a controlled manner.

According to an embodiment, the substrate holder can be moved in a direction parallel to the lower face of the substrate.

According to a particular embodiment, the method described above is carried out by means of the system described above.

In the following, the invention will be discussed in more detail with reference to the drawings in the meaning of an example (magnetic multi-layers). Moreover, also other methods for coating the substrates that have been brought to a defined temperature can be possible and intended in accordance with the invention.

### BRIEF DESCRIPTION OF THE DRAWINGS

FIG. 1 schematically shows a typical layer structure with upper and lower electrodes as used, e.g., by TMR layer systems for MRAM and TFH;

FIG. 2 schematically shows an example of cathode sputtering using a target with corresponding magnet array and a substrate on the way into the coating zone;

FIGS. 3a to 3c schematically show the course of the method for heating a substrate;

FIG. 4 schematically shows a temperature profile of a substrate;

FIG. 5 schematically shows the principle of FIG. 2 with substrate holder; and

FIG. 6 schematically shows the arrangement of a heat accumulator on the substrate holder.

### DETAILED DESCRIPTION OF THE INVENTION

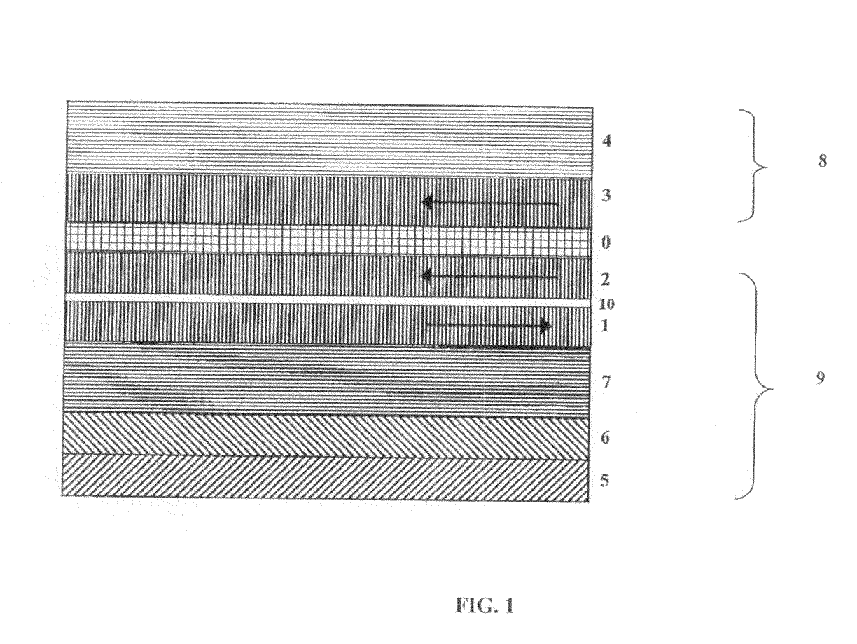

FIG. 1 exemplarily shows a typical TMR layer package. The layers 1, 2 (having specific magnetic orientations, “pinned and reference layer”) and the layer 2 (“free layer”) are made of a ferromagnetic material and separated from each other by a magnesium oxide layer 0. The shown arrows indicate the direction of the magnetization which lies in the layer plane. The thicknesses of the individual layers vary from less than 1.0 nm up to some 10.0 nm. The layer 3 (“free layer”) together with a layer 4 (“capping layer”) form the upper electrode 8. The lower electrode 9 consists of layers 5 (“seed layer no. 1”) and 6 (“seed layer no. 2”) and the layer 7 (“pinning layer” made of an anti-ferromagnetic material such as PtMn, IrMn), as well as of the packet of the layers 1 (“pinned layer”), 10 (“coupling layer”) and 2 (“reference layer”).

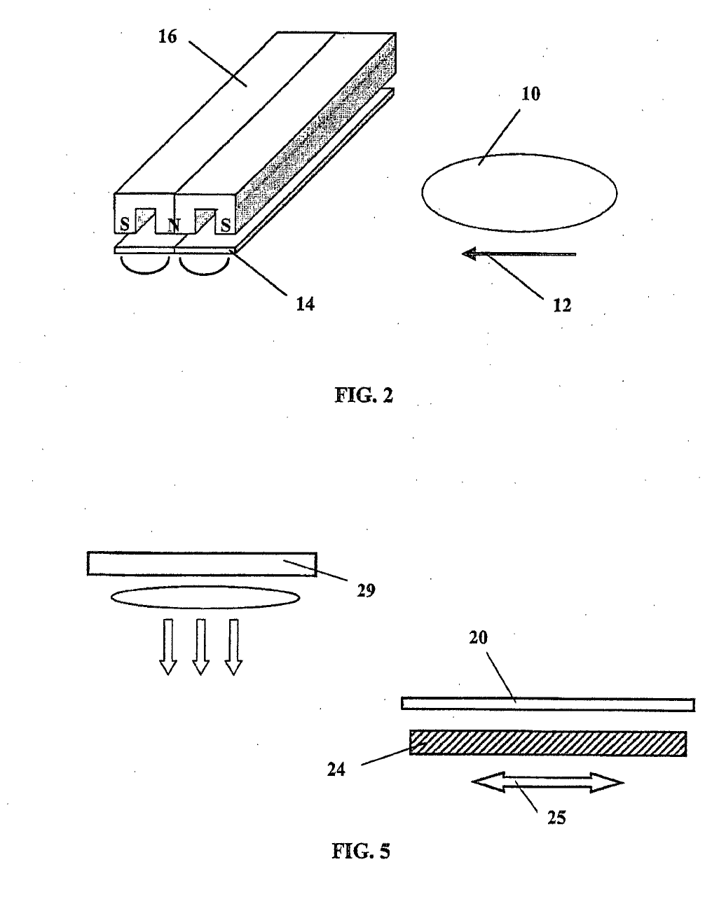

In the meaning of an example, a specific procedure for producing multi-layers by means of cathode sputtering will be described in the following on the basis of FIG. 2, wherein substrates are coated with individual materials at a defined—optionally high—temperature as described above. The sputtering cathode comprises a magnet array 16 in order to bundle the electrons which are responsible for the ionization of the plasma in the vicinity of the surface of the target 14. During this “linear dynamic” deposition (LDD), the substrate 10, e.g. a (silicon) wafer, is passed in a straight line under the (e.g. rectangular) sputtering cathode 14, 16 (see direction of arrow 12), so that the coating takes place (dynamically) during the passage.

This procedure is, e.g., in contrast to the methods common in the semiconductor industry in which the wafer rests without relative movement, i.e. statically, under the coating cathode during the coating process.

The LDD method can now be combined with a device comprising a plurality of coating cathodes so that various layers can be applied alternatingly to the substrate without time loss. Thus, it is, e.g., also possible to produce the desired multi-layers from different materials without relatively long transporting times. In order to move the substrate 10 for the coating steps, it is held on a substrate holder. The latter can be, e.g., a (water) cooled ESC whose surface comprises integrated channels for an improved dissipation of thermal energy so that helium or argon can be used as contact agent between substrate 10 and ESC.

When producing multi-layers by means of the LDD, e.g., first the substrate 10 is transported by means of a robot from a vacuum transport chamber into the coating chamber and placed onto the chuck (substrate holder). Transport chamber and coating chamber can then be separated from each other by means of a lock valve. Once an electrical voltage has been applied, the substrate 10 can be fixed on the chuck by means of electrostatic forces. Moreover, a gas cushion can be/have been generated under the substrate 10 for achieving a good cooling. The “cooling gas” can be kept off the remaining vacuum chamber by means of seals.

The selected sputtering cathode 14, 16 is ignited and the substrate 10 moved one or more times through the coating zone until the desired layer thickness has been achieved. Subsequently, the next cathode can be selected and ignited and thus the next layer of the stack can be applied, etc.

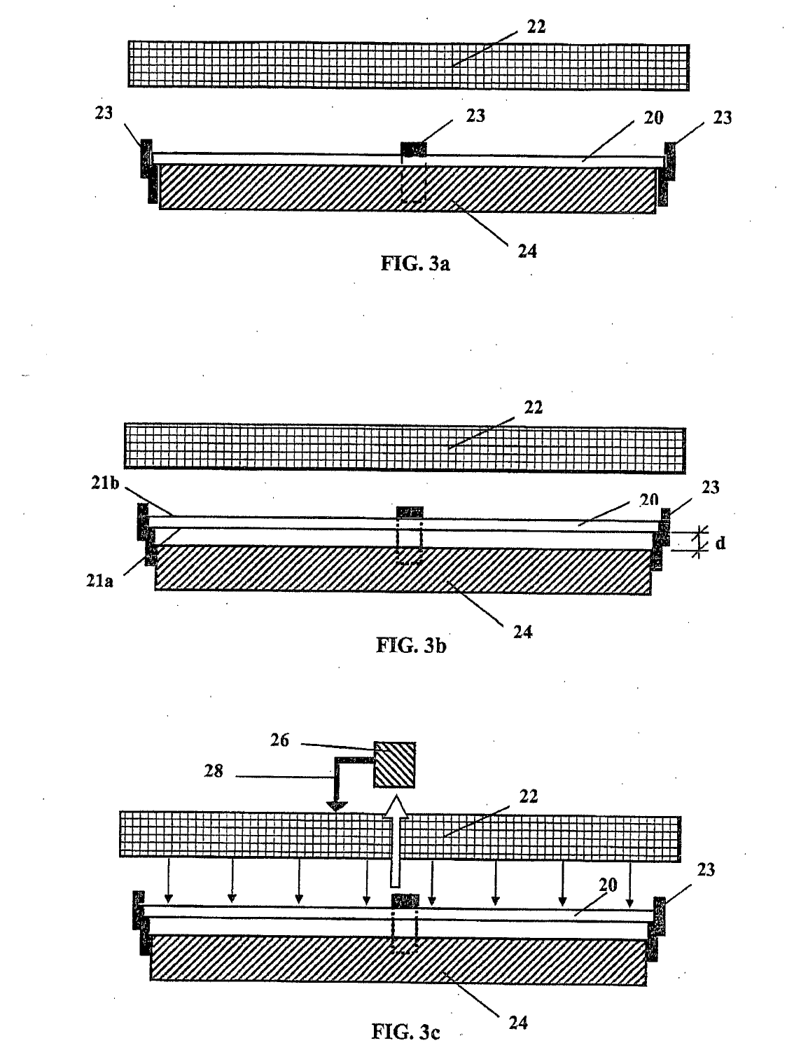

On the basis of FIGS. 3a to 3c, the principle of the present invention will now be explained in more detail. The substrate 20 can be heated quickly in that, e.g., the substrate holder 24 with the substrate 20 thereon is moved within the vacuum chamber prior to coating into a heating station in which a heating device 22, e.g. a radiant heater or an array of radiant heaters, is positioned above the substrate 20 (wafer) or the chuck 24 opposite the upper face 21b of the substrate 20. Before the heating step, first the lower face 21a of the substrate 20 rests on the chuck 24, as shown in FIG. 3a. In this state of the substrate 20, already one or more layers could have been applied to the substrate at room temperature or at other temperatures, or the substrate does not yet have any coating.

For heating, the substrate 20 is lifted from the chuck 24, for example such that it does no longer contact the latter via the lower face 21a of the substrate 20. A specific lock can, e.g., assure that the substrate 20 remains connected with the chuck 24, e.g., via three or four “fingers” 23, which hold the substrate 20 at the edge and are configured such that they have a slight and/or negligible thermal conductivity, but a distance d of some (e.g. 2 to 3) millimeters is maintained, as indicated in FIG. 3b.

Subsequently, the heating device 22 is switched on and the substrate 20 is brought to the desired temperature. The temperature can be measured, e.g., by means of a pyrometer 26. The speed of the temperature increase and/or the final temperature can be set by a control circuit 26, 28, as shown in FIG. 3c. Since the substrate 20 itself, e.g., has only a small thermal mass, a fast temperature increase can be achieved. The overall structure of the substrate holder 24 and the installation of suitable cooled shields can moreover guarantee that possibly only the substrate 20 is heated while the temperature of other parts of the substrate holder 24 is raised as little as possible.

The substrate 20 shields the substrate holder against the radiation of the heating device 22 (at least partially) so that the temperature of the substrate holder 24 changes very little and preferably remains constant.

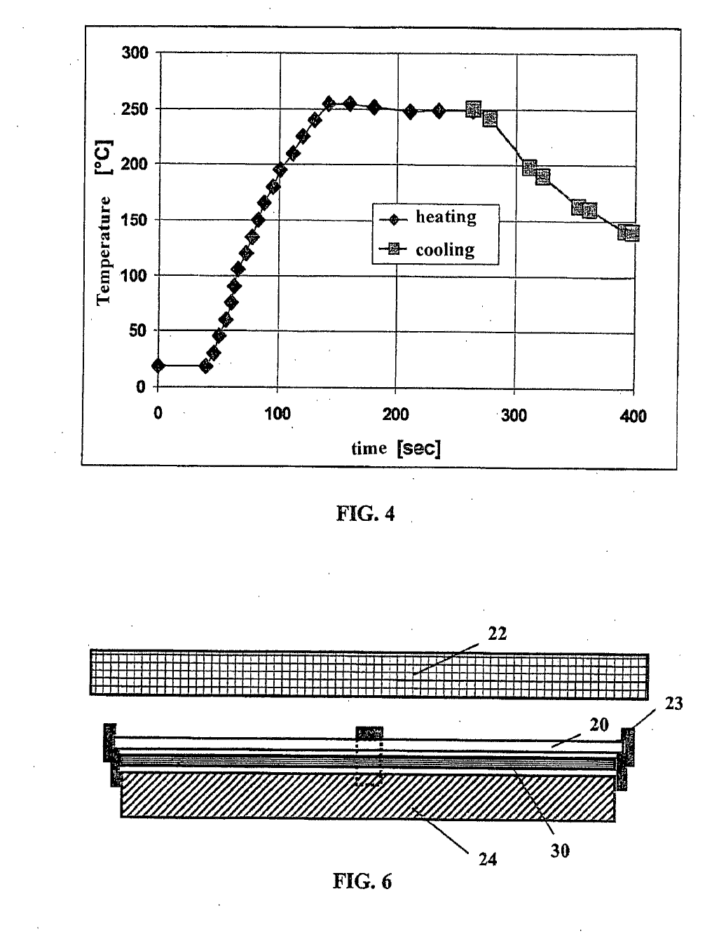

A typical temperature profile of the substrate is shown in FIG. 4.

FIG. 5 shows—in accordance with the principle of FIG. 2—how a substrate, in this case a substrate 20, which has already been heated by the heating device and brought to the desired temperature, can be coated. As soon as the desired temperature has been reached, the chuck 24 with the lifted hot substrate can be moved or can move in an automatically controlled manner (see direction of the arrow 25) so that the (next) coating can be applied, as indicated in FIG. 5. Since the time between the heating of the substrate 20 and the coating is very short (e.g. only some seconds), the substrate is not or only slightly cooled until the coating process starts.

If the substrate cools too much, mainly during several coating passages, a further heating step can be provided between the coating processes and, for this purpose, the substrate 20 can be moved out of the cathode sputtering station 29 by means of the substrate holder 24 and transported under the heating device and finally back to a coating station.

After coating at a high temperature, the substrate 20 and the chuck 24 can, e.g., again be brought into the position under the heater and the substrate 20 can be placed on the chuck 24, optionally also pressed electrostatically onto the chuck 24. By means of the cooled chuck 24 and by using the contact gas, the substrate 20 can be cooled rapidly. For example, by adjusting the pressure of the contact gas, the cooling rate can be adjusted.

Subsequently, e.g., also in another coating station, further layers of the layer system can be applied to the cooled/cold substrate, e.g., at room temperature or any other temperature.

According to the invention, a heat accumulator 30 which has previously been brought to a desired temperature can moreover be introduced between the lifted substrate 20 and the chuck 24 in order to compensate for a possible temperature drop. The heat accumulator 30 has, e.g., a large thermal mass and preferably can be black on the side facing the substrate 20 but can be prepared on all other surfaces or at least on the surface facing the chuck such that the heat radiation is minimal. This heat accumulator 30 can, e.g., also be moved to and fro together with the substrate and the substrate holder for the purpose of coating in order to minimize the cooling of the substrate during coating.

According to an embodiment, the lamps of the radiant heater can be coated with filter layers so that the irradiated infrared light contains only such wavelengths which are absorbed either mainly by the substrate (typically silicon) or alternatively mainly by the already deposited layer system.

Therefore, in accordance with the present invention a substrate to be coated can be quickly heated and cooled to defined temperatures, optionally with immediately subsequent coating, so that a plurality of layers can be deposited on the substrate very effectively at different temperatures within the shortest possible time.

1. A method for heating a substrate (20) and immediately subsequently coating the substrate in a vacuum chamber, comprising the following steps:
(a) arranging the substrate (20) on a substrate holder (24) so that the lower face (21a) of the substrate contacts the substrate holder in a face-to-face manner,
(b) lifting the substrate (20) relative to the substrate holder by a distance d,
(c) heating the lifted substrate via its upper face (21b) by means of a heating device (22),
(d) immediately subsequently coating the hot substrate, and
(e) lowering the substrate to the substrate holder (24) and cooling the substrate.

2. The method according to claim 1, wherein the cooled substrate is coated.

3. The method according to claim 1, wherein the heating device (22) is controlled via a temperature sensor (26, 28) for determining a substrate temperature and via a temperature control device for setting a predetermined temperature.

4. The method according to claim 1, wherein step (d) comprises immediately moving the heated substrate together with the substrate holder (24) into the coating position and coating the substrate.

5. The method according to claim 1 wherein the substrate (20) is lifted in method step (b) by 0.1 to 20 mm relative to the substrate holder (24).

6. The method according to claim 1, wherein the heating device consists of infrared radiators using filter layers so that irradiated infrared light contains only such wavelengths which are absorbed either by the substrate or by the already deposited layer system.

7. The method according to claim 1, comprising the step:
arranging a heat accumulator (30) between the substrate holder (24) and the lifted substrate (20).

8. The method according to claim 1, wherein the substrate holder (24) is cooled.

9. The method according to claim 1, wherein immediately after cooling, the cooled substrate is moved together with the substrate holder (24) into the coating position and coated there.

10. The method according to claim 1, wherein tempering of the substrate to various temperatures with subsequent coating is performed sequentially in several individual steps.

11. A system for heating a substrate (20) in a vacuum chamber comprising
a substrate holder (24),
a lifting device (23) for lifting the substrate (20) whose lower face (21a) is arranged on the substrate holder (24), and
a heating device (22) for heating the lifted substrate (20) via its upper face.

12. The system according to claim 11, wherein the lifting device (23) is configured so as to prevent a significant heat flow between substrate holder (24) and substrate (20).

13. The system according to claim 11, wherein the substrate holder (24) comprises at least one channel for a contact gas and the system comprises a controller for cooling the substrate holder (24) in a controlled manner.

14. The system according to claim 11, comprising a temperature sensor (26, 28) for heating the substrate (20) in a controlled manner.

15. The system according to claim 11, wherein the lifting device is provided at the substrate holder (24).

16. The system according to claim 11, wherein the substrate holder (24), with the substrate (20), can be moved in a direction parallel (25) to a lower face (21a) of the substrate.

17. The method according to claim 5 wherein the substrate (20) is lifted in step (b) by 1 to 10 mm relative to the substrate holder.
